(19) United States
(12) Patent Application Publication
(10) Pub. No.: US 2005/0218420 A1
(43) Pub. Date: Oct. 6, 2005

(54) Semiconductor laser apparatus and fabrication method thereof

(75) Inventors: Yasuyuki Bessho, Osaka (JP); Masayuki Hata, Osaka (JP); Daijiro Inoue, Kyoto-shi (JP); Tsutomu Yamaguchi, Nara-shi (JP)

Correspondence Address: MCDERMOTT WILL & EMERY LLP, 600 13TH STREET, N.W., WASHINGTON, DC, 20005-3096, US

(73) Assignee: SANYO ELECTRIC CO., LTD.

(21) Appl. No.: 11/076,963

(22) Filed: Mar. 11, 2005

(30) Foreign Application Priority Data
Mar. 30, 2004 (JP) 2004-101486

(51) Int. Cl. H01L 33/00; H01L 21/00

(52) U.S. Cl. 257/99; 438/22; 257/89; 438/28; 257/706

(57) ABSTRACT

A blue-violet semiconductor laser device has a p-electrode formed on the upper surface thereof and an n-electrode formed on the lower surface thereof. In the blue-violet semiconductor laser device, a p-n junction surface is formed where a p-type semiconductor and an n-type semiconductor are joined. A red semiconductor laser device has an n-electrode formed on the upper surface thereof and a p-electrode formed on the lower surface thereof. In the red semiconductor laser device, a p-n junction surface is formed where a p-type semiconductor and an n-type semiconductor are joined. The p-electrode of the red semiconductor laser device is bonded to the p-electrode of the blue-violet semiconductor laser device such that the red semiconductor laser device does not overlap with a blue-violet-beam-emission point of the blue-violet semiconductor laser device.

### BACKGROUND OF THE INVENTION

1. Field of the Invention

The present invention relates to a semiconductor laser apparatus that can emit a plurality of light beams with different wavelengths and a fabrication method thereof.

2. Description of the Background Art

Conventionally, CD (Compact Disk)/CD-R (Compact Disk-Recordable) drives have employed semiconductor laser devices which emit infrared beams of light with a wavelength of approximately 780 nm (infrared semiconductor laser devices) as light sources. DVD (Digital Versatile Disk) drives, on the other hand, have employed semiconductor laser devices which emit red beams of light with a wavelength of approximately 650 nm (red semiconductor laser devices) as light sources.

Meanwhile, the development of DVDs is recently progressing which can be recorded and played back using blue-violet beams of light with a wavelength of approximately 405 nm. In order to record and play back such DVDs, the development of DVD drives using semiconductor laser devices which emit blue-violet beams of light with a wavelength of approximately 405 nm (blue-violet semiconductor laser devices) is simultaneously progressing. Such DVD drives require compatibility with conventional CDs/CD-Rs and DVDs.

In this case, compatibility with conventional CDs, DVDs, and new DVDs is achieved using a method of providing a DVD drive with a plurality of optical pickup apparatuses which emit infrared, red, and blue-violet beams, respectively, or a method of providing an infrared semiconductor laser device, red semiconductor laser device, and blue-violet semiconductor laser device in one optical pickup apparatus. The above-described methods, however, result in an increase in parts count, thus making it difficult to make a smaller, simpler, and lower-cost DVD drive.

In order to prevent such an increase in the parts counts, semiconductor laser devices comprised of an infrared semiconductor laser device and a red semiconductor laser device integrated into a single chip are in practical use.

The infrared semiconductor laser device and red semiconductor laser device, which are both formed on a GaAs substrate, can be formed into a single chip. The blue-violet semiconductor laser device, however, is not formed on a GaAs substrate, which makes it very difficult to be integrated into a single chip together with the infrared and red semiconductor laser devices.

For this reason, an integrated semiconductor light emitting device is suggested, which is fabricated by forming a chip of a red semiconductor laser device and a chip of a blue-violet semiconductor laser device, and laminating the red semiconductor laser device chip on the blue-violet semiconductor laser device chip (refer to e.g. JP 2002-118331 A).

However, the above-described integrated semiconductor light emitting device dissipates heat from the red semiconductor laser device via the blue-violet semiconductor laser device during driving, and therefore, efficient heat dissipation from the integrated semiconductor laser device itself is very difficult. It has therefore been pointed out that the insufficient heat dissipation has degraded the reliability of the integrated semiconductor light emitting device.

### SUMMARY OF THE INVENTION

An object of the present invention is to provide a semiconductor laser apparatus that can efficiently dissipate heat from a plurality of semiconductor laser devices and also has increased reliability, and a method of fabricating such a semiconductor laser apparatus.

According to one aspect of the present invention there is provided a semiconductor laser apparatus comprising: a first semiconductor laser device having on a first substrate a first semiconductor layer that emits a light beam with a first wavelength; and a second semiconductor laser device having on a second substrate a second semiconductor layer that emits a light beam with a second wavelength, wherein the first and the second wavelengths are different from each other, and materials of the first and the second substrates are different from each other, the second semiconductor laser device being laminated on the first semiconductor laser device so as not to overlap with a light-beam-emission point of the first semiconductor laser device in a vertical direction to one surface of the first substrate.

In the semiconductor laser apparatus, the second semiconductor laser device is laminated on the first semiconductor laser device such that the second semiconductor laser device does not overlap with the light-beam-emission point of the first semiconductor laser device in the vertical direction to the one surface of the first substrate.

This allows heat produced from the light-beam-emission point of the first semiconductor laser device to be efficiently dissipated without being inhibited by the second semiconductor laser device. Also, heat produced from the second semiconductor laser device is efficiently dissipated without being inhibited by the light-beam-emission point of the first semiconductor laser device. This results in enhanced temperature characteristics and reliability.

The first semiconductor laser device may have a difference in level formed by an upper level surface and a lower level surface, the light-beam-emission point of the first semiconductor layer being arranged below the upper level surface, and the second semiconductor laser device being laminated on the lower level surface of the first semiconductor laser device.

In this manner, the second semiconductor laser device is laminated on the lower level surface of the first semiconductor laser device, so that the upper level surface of the first semiconductor laser device and the upper surface of the laminated second semiconductor laser device can be formed at substantially the same level. This allows the upper level surface of the first semiconductor laser device and the upper surface of the second semiconductor laser device to come into contact with a flat, inexpensive heat dissipator. Consequently, the use of the flat and inexpensive heat dissipator is possible, thereby reducing the manufacturing cost.

Moreover, the light-beam-emission point of the first semiconductor layer in the first semiconductor laser device is positioned below the upper level surface, while the light-beam-emission point of the second semiconductor laser device in the second semiconductor laser device is positioned above the lower level surface. This allows the light-beam-emission points of the first and the second semiconductor laser devices to be aligned in a parallel direction with the one surface of the first substrate. This facilitates the designs of the semiconductor laser apparatus and an optical pickup apparatus therefore.

The second semiconductor laser device may be laminated on the first semiconductor laser device such that the second semiconductor layer side is positioned on the first semiconductor layer side. In this manner, the second semiconductor laser device is laminated on the first semiconductor laser device such that the second semiconductor layer side is positioned on the first semiconductor layer side, which shortens the distance between the light-beam-emission points of the first semiconductor laser device and the second semiconductor laser device. Thus, the light-beam-emission points of both the first and the second semiconductor laser devices can become closer to the center of the semiconductor laser apparatus. This results in enhanced light extraction efficiencies of both the first and the second semiconductor laser devices when converging laser beams through a lens, for example.

Either of the first semiconductor layer and the second semiconductor layer may be made of a nitride-based semiconductor. In this manner, either of the first semiconductor layer and the second semiconductor layer is made of the nitride-based semiconductor with a high thermal conductivity, which results in enhanced heat dissipation from the semiconductor layer of either of the first semiconductor laser device or the second semiconductor laser device. This enhances the temperature characteristics and reliability of either of the first or the second semiconductor laser device. This also enables emission of a blue-violet laser beam with short wavelength.

The first substrate may be an optically transparent substrate. The optically transparent substrate as used herein has such transmittance and thickness that allows the second semiconductor laser device to be visually seen through the first substrate. In this case, with the first substrate being an optically transparent substrate, the semiconductor laser apparatus can be visually seen therethrough in the lamination of the second semiconductor laser device on the first semiconductor laser device. This facilitates the positioning of the second semiconductor laser device. Consequently, the position on which the second semiconductor laser device is laminated can be accurately determined. Thus, the positioning accuracy for the light-beam-emission points of the first and the second semiconductor laser devices can be enhanced.

The second semiconductor laser device may be laminated on the first semiconductor laser device such that the first semiconductor layer is positioned on the second semiconductor laser device side.

In this manner, the second semiconductor laser device is laminated on the first semiconductor laser device such that the first semiconductor layer is positioned on the second semiconductor laser device side. This shortens the distance between the light-beam-emission points of the first semiconductor laser device and the second semiconductor laser device. Thus, the light-beam-emission points of both the first and the second semiconductor laser devices can become closer to the center of the semiconductor laser apparatus. This results in enhanced light extraction efficiencies of both the first and the second semiconductor laser devices when converging laser beams through a lens, for example.

Either of the first semiconductor layer and the second semiconductor layer may include a gallium arsenide-based semiconductor or a gallium indium phosphide-based semiconductor. The semiconductor laser apparatus is capable of emitting an infrared laser beam with long wavelength when either of the first semiconductor layer or the second semiconductor layer includes a gallium arsenide-based semiconductor. The semiconductor laser apparatus is capable of emitting a red laser beam with long wavelength when either of the first semiconductor layer or the second semiconductor layer includes a gallium indium phosphide-based semiconductor.

A heat dissipator may be arranged in contact with a region on the first semiconductor laser device which overlaps with the light-beam-emission point of the first semiconductor layer and a surface of the second semiconductor laser device on the opposite side of the first semiconductor laser device.

In this manner, the heat dissipator is arranged on the region on the first semiconductor laser device which overlaps with the light-beam-emission point of the first semiconductor layer and on the surface of the second semiconductor laser device on the opposite side of the first semiconductor laser device. This allows the heat produced from the first semiconductor layer and the heat produced from the second semiconductor layer in the second semiconductor laser device to be efficiently transmitted to the heat dissipator. This enhances the heat dissipation and reliability of the first and the second semiconductor laser devices.

The second semiconductor laser device may be laminated on the first semiconductor laser device, so that one surface of the first semiconductor laser device and one surface of the second semiconductor laser device form a difference in level, the heat dissipator being provided with a difference in level formed by a first surface in contact with the one surface of the first semiconductor laser device and a second surface in contact with the one surface of the second semiconductor laser device.

In this case, the heat produced from the light-beam-emission point of the first semiconductor layer is efficiently transmitted from the first surface to the heat dissipator. Also, the heat produced from the light-beam-emission point of the second semiconductor layer is efficiently transmitted from the second surface to the heat dissipator. This enhances heat dissipation and reliability of the first and the second semiconductor laser devices.

The semiconductor laser apparatus may further comprise a third semiconductor laser device having a third semiconductor layer on a third substrate that emits a light beam with a third wavelength, wherein the third semiconductor laser device is laminated on the first semiconductor laser device except a region that overlaps with the light-beam-emission point of the first semiconductor laser device in a parallel direction with the one surface of the first substrate.

In this case, the third semiconductor laser device is laminated on the first semiconductor laser device such that the third semiconductor laser device does not overlap with the light-beam-emission point of the first semiconductor laser device in the parallel direction with the one surface of the first substrate.

This allows the heat produced from the light-beam-emission point of the first semiconductor laser device to be efficiently dissipated without being inhibited by the third semiconductor laser device. Also, the heat produced from the third semiconductor laser device is efficiently dissipated without being inhibited by the first semiconductor laser device. This results in enhanced temperature characteristics and reliability.

The second and the third semiconductor laser devices may be laminated on the first semiconductor laser device such that the first semiconductor layer is positioned on the second and the third semiconductor laser devices sides.

In this manner, the second and the third semiconductor laser devices are laminated on the first semiconductor laser device such that the first semiconductor layer is positioned on the second and the third semiconductor laser devices side. This shortens the distances between the light-beam-emission point of the first semiconductor laser device and the light-beam-emission points of the second and the third semiconductor laser devices. In this manner, the light-beam-emission points of all of the first, second, and third semiconductor laser devices can become closer to the center of the semiconductor laser apparatus. This results in enhanced light extraction efficiencies of all of the first, second, and third semiconductor laser devices when converging laser beams through a lens, for example.

The second semiconductor laser device may be laminated on the first semiconductor laser device such that the second semiconductor layer side is positioned on the first semiconductor layer side. In this manner, the second semiconductor laser device is laminated on the first semiconductor laser device such that the second semiconductor layer side is positioned on the first semiconductor layer side, which shortens the distance between the light-beam-emission points of the first semiconductor laser device and the second semiconductor laser device. In this manner, the light-beam-emission points of both the first and the second semiconductor laser devices can become closer to the center of the semiconductor laser apparatus. This results in enhanced light extraction efficiencies of the first and the second semiconductor laser devices when converging laser beams through a lens, for example.

The third semiconductor laser device may be laminated on the first semiconductor laser device such that the third semiconductor layer side is positioned on the first semiconductor layer side. In this manner, the third semiconductor laser device is laminated on the first semiconductor laser device such that the third semiconductor layer side is positioned on the first semiconductor layer side, which shortens the distance between the light-beam-emission points of the first semiconductor laser device and the third semiconductor laser device. In this manner, the light-beam-emission points of both the first and the third semiconductor laser devices can become closer to the center of the semiconductor laser apparatus. This results in enhanced light extraction efficiencies of both the first and the third semiconductor laser devices when converging laser beams through a lens, for example.

The first, the second, and the third wavelengths may be different from one another, and the first, the second, and the third semiconductor layers may include any of a nitride-based semiconductor, a gallium arsenide-based semiconductor or a gallium indium phosphide-based semiconductor.

The semiconductor laser apparatus is capable of emitting a blue-violet laser beam with short wavelength, an infrared laser beam with long wavelength, and a red laser beam with long wavelength by the inclusion of any of the nitride-based semiconductor, gallium arsenide-based semiconductor or gallium indium phosphide-based semiconductor in the first, second, and third semiconductor layers, respectively.

A heat dissipator may be arranged in contact with a region on the first semiconductor laser device which overlaps with the light-beam-emission point of the first semiconductor layer, a surface of the second semiconductor laser device on the opposite side of the first semiconductor laser device, and a surface of the third semiconductor laser device on the opposite side of the first semiconductor laser device.

In this manner, the heat dissipator is arranged on the region on the first semiconductor laser device which overlaps with the light-beam-emission point of the first semiconductor layer, on the surface of the second semiconductor laser device on the opposite side of the first semiconductor laser device, and on the surface of the third semiconductor laser device on the opposite side of the first semiconductor laser device. This allows the heat produced from the light-beam-emission point of the first semiconductor layer, the heat produced from the light-beam-emission point of the second semiconductor layer in the second semiconductor laser device, and the heat produced from the light-beam-emission point of the third semiconductor layer in the third semiconductor laser device to be efficiently transmitted to the heat dissipator. This results in enhanced heat dissipation and reliability of the first, second, and third semiconductor laser devices.

According to another aspect of the present invention there is provided a method of fabricating a semiconductor laser apparatus comprising the steps of: forming on a first substrate a first semiconductor layer such that the first semiconductor layer has a plurality of first light-beam-emission points that emit light beams with a first wavelength; forming a second semiconductor layer on a second substrate made of a different material from that of the first substrate such that the second semiconductor layer has a plurality of second light-beam-emission points that emit light beams with a second wavelength different from the first wavelength; bonding the first substrate and the second substrate such that the second semiconductor layer is laminated on the first semiconductor layer; etching the second substrate and the second semiconductor layer such that regions of the first semiconductor layer above the plurality of first light-beam-emission points become exposed; and dividing a layered structure of the first semiconductor layer, the second substrate, and the second semiconductor layer into a plurality of semiconductor laser apparatuses.

In the method of fabricating the semiconductor laser apparatus, the first semiconductor layer is formed on the first substrate such that the first semiconductor layer has the plurality of first light-beam-emission points, and then the second semiconductor layer is formed on the second substrate such that the second semiconductor layer has the plurality of second light-beam-emission points. After this, the first substrate and the second substrate are bonded such that the second semiconductor layer is laminated on the first semiconductor layer, followed by etching of the second substrate and the second semiconductor layer such that the regions of the first semiconductor layer above the plurality of first light-beam-emission points become exposed. Finally, the layered structure of the first substrate, the first semiconductor layer, the second substrate, and the second semiconductor layer is divided into the plurality of semiconductor laser apparatuses.

Thus, a semiconductor laser apparatus is obtained in which the second semiconductor laser device is laminated on the first semiconductor laser device such that the second semiconductor laser device does not overlap with the light-beam-emission point of the first semiconductor laser device in the parallel direction with the one surface of the first substrate.

In the semiconductor laser apparatus, the heat produced from the first light-beam-emission point of the first semiconductor laser device is efficiently dissipated without being inhibited by the second semiconductor laser device, and also the heat produced from the second light-beam-emission point of the second semiconductor laser device is efficiently dissipated without being inhibited by the first semiconductor laser device. This results in enhanced temperature characteristics and reliability.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross section showing an exemplified semiconductor laser according to a first embodiment;

FIG. 2 is a schematic cross section of the semiconductor laser apparatus of FIG. 1 when assembled on a heat sink;

FIGS. 3(a) and 3(b) are schematic cross sections showing exemplified steps of the fabrication method of the semiconductor laser apparatus according to the first embodiment;

FIGS. 4(c) and 4(d) are schematic cross sections showing exemplified steps of the fabrication method of the semiconductor laser apparatus according to the first embodiment;

FIGS. 5(e) and 5(f) are schematic cross sections showing exemplified steps of the fabrication method of the semiconductor laser apparatus according to the first embodiment;

FIG. 6(g) is a schematic cross section showing an exemplified step of the fabrication method of the semiconductor laser apparatus according to the first embodiment;

FIGS. 7(a) and 7(b) are schematic cross sections for use in illustrating the structure of the blue-violet semiconductor laser device in detail;

FIGS. 8(a) and 8(b) are schematic cross sections for use in illustrating the structure of the red semiconductor laser device in detail;

FIG. 9 is a schematic cross section of a semiconductor laser apparatus according to a second embodiment when assembled on a heat sink;

FIG. 10 is a schematic cross section of a semiconductor laser apparatus according to another example of the second embodiment when assembled on a heat sink;

FIG. 11 is a schematic cross section of a semiconductor laser apparatus according to a third embodiment when assembled on a heat sink; and

FIG. 12 is a schematic cross section of a semiconductor laser apparatus according to a fourth embodiment when assembled on a heat sink.

### DESCRIPTION OF THE PREFERRED EMBODIMENTS

A semiconductor laser apparatus according to an embodiment of the present invention and a fabrication method thereof will now be described.

### First Embodiment

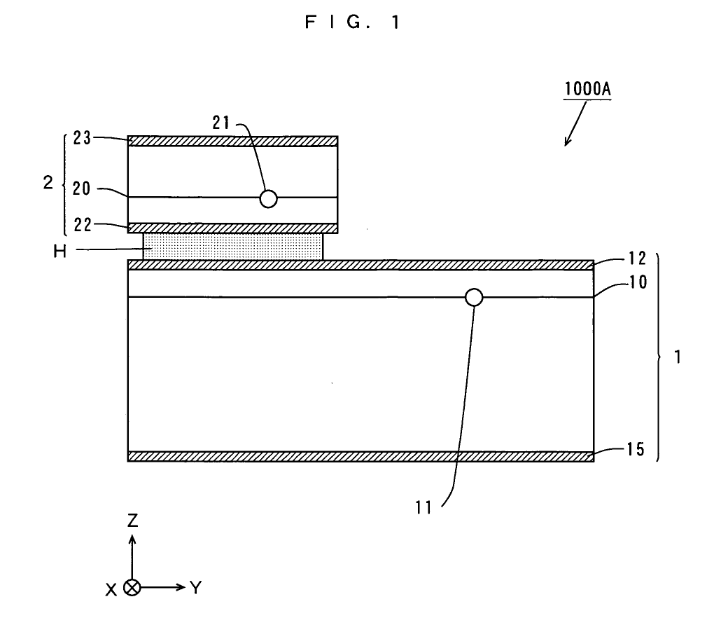

FIG. 1 is a schematic cross-section showing an exemplified semiconductor laser according to a first embodiment.

The semiconductor laser apparatus 1000A according to the present embodiment comprises a semiconductor laser device (hereinafter referred to as a blue-violet semiconductor laser device) 1 which emits a laser beam with a wavelength of approximately 400 nm and a semiconductor laser device (hereinafter referred to as a red semiconductor laser device) 2 which emits a laser beam with a wavelength of approximately 650 nm.

In this embodiment, the blue-violet semiconductor laser device 1 is fabricated by forming semiconductor layers on a GaN substrate. The red semiconductor laser device 2 is fabricated by forming semiconductor layers on a GaAs substrate. The fabrication of these semiconductor laser devices will be discussed in detail below.

As shown in FIG. 1, the blue-violet semiconductor laser device 1 has a p-electrode 12 formed on the upper surface thereof and an n-electrode 15 formed on the lower surface thereof. In the blue-violet semiconductor laser device 1, a p-n junction surface 10 is formed where a p-type semiconductor and an n-type semiconductor are joined.

The red semiconductor laser device 2 has an n-electrode 23 formed on the upper surface thereof and a p-electrode 22 formed on the lower surface thereof. In the red semiconductor laser device 2, a p-n junction surface 20 is formed where a p-type semiconductor and an n-type semiconductor are joined.

The blue-violet semiconductor laser device 1 has a solder film H which is partially formed on the upper surface of the p-electrode 12. The p-electrode 22 of the red semiconductor laser device 2 is bonded to the p-electrode 12 via the solder film H. The portion of the p-electrode 12 on which the solder film H is not formed is exposed.

This results in an electrical connection between the p-electrode 12 of the blue-violet semiconductor laser device 1 and the p-electrode 22 of the red semiconductor laser device 2. In this manner, the p-electrode 12 of the blue-violet semiconductor laser device 1 and the p-electrode 22 of the red semiconductor laser device 2 become the common electrodes.

In FIG. 1, the arrows X, Y, Z indicate three directions, X-direction, Y-direction, and Z-direction, which are orthogonal to one another. The X- and Y-directions are in parallel with the p-n junction surfaces 10, 20 of the blue-violet semiconductor laser device 1 and the red semiconductor laser device 2. The Z-direction is vertical to the p-n junction surfaces of the blue-violet semiconductor laser device 1 and the red semiconductor laser device 2.

When voltage is applied between the p-electrode 12 and the n-electrode 15 in the blue-violet semiconductor laser device 1, a laser beam with a wavelength of approximately 400 nm is emitted in the X-direction from a predetermined region (hereinafter referred to as a blue-violet-beam-emission point) 11 in the p-n junction surface 10. The blue-violet-beam-emission point 11 is situated at a different position from the connection position of the blue-violet semiconductor laser device 1 and the red semiconductor laser device 2 in the Y-direction.

When voltage is applied between the p-electrode 22 and the n-electrode 23 in the red semiconductor laser device, a laser beam with a wavelength of approximately 650 nm is emitted in the X-direction from a predetermined region (hereinafter referred to as a red-beam-emission point) 21 in the p-n junction surface 20.

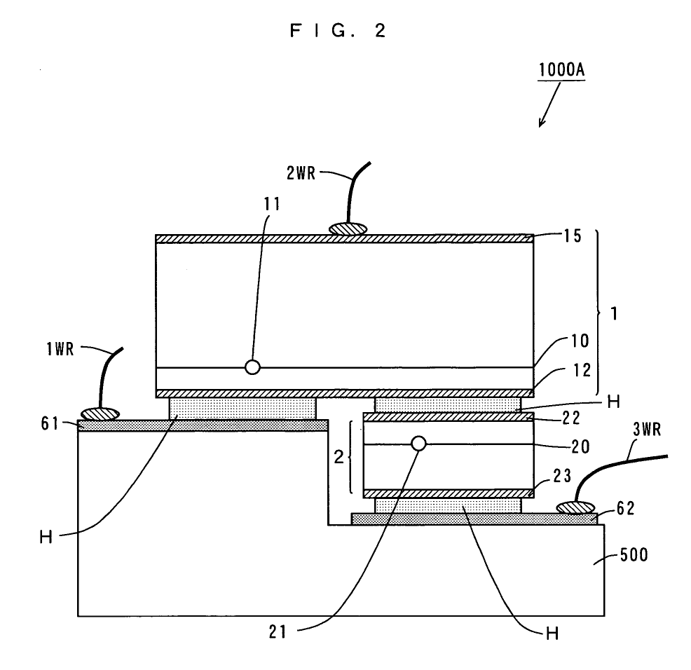

FIG. 2 is a schematic cross-section of the semiconductor laser apparatus 1000A of FIG. 1 when assembled on a heat sink. When the semiconductor laser apparatus 1000A of FIG. 1 is used in an optical pickup apparatus, it is mounted on the heat sink 500 made of an insulative material with good thermal conductivity, such as AlN, SiC, Si, or diamond, as shown in FIG. 2.

Note that the upper surface of the heat sink 500 of FIG. 2 has a difference in level. Patterning electrodes 61, 62 are formed, respectively, on the upper level and lower level surfaces of the heat sink 500. The patterning electrodes 61, 62 are electrically isolated from each other.

Solder films H are partially formed on the upper surfaces of the patterning electrodes 61, 62. The p-electrode 12 of the blue-violet semiconductor laser device 1 and the p-electrode 22 of the red semiconductor laser device 2 are bonded via the solder film H to the patterning electrode 61 on the upper level surface. The n-electrode 23 of the red semiconductor laser device 2 is bonded via the solder film H to the patterning electrode 62 on the lower level surface.

This results in an electrical connection among the p-electrode 12 of the blue-violet semiconductor laser device 1, the p-electrode 22 of the red semiconductor laser device 2, and the patterning electrode 61 of the heat sink 500. The n-electrode 23 of the red semiconductor laser device 2 and the patterning electrode 62 of the heat sink 500 are also electrically connected.

In this state, the p-electrode 12 and the n-electrode 15 of the blue-violet semiconductor laser device 1 as well as the p-electrode 22 and the n-electrode 23 of the red semiconductor laser device 2 are wired, using wires 1WR, 2WR, 3WR.

The patterning electrode 61, which is electrically connected with the p-electrode 12 of the blue-violet semiconductor laser device 1 and the p-electrode 22 of the red semiconductor laser device 2, is connected through the wire 1WR to a driving circuit (not shown). The n-electrode 15 of the blue-violet semiconductor laser device 1 is connected to the driving circuit (not shown) through the wire 2WR. The patterning electrode 62, which is bonded to the n-electrode 23 of the red semiconductor laser device 2, is connected to the driving circuit (not shown) through the wire 3WR.

Application of voltage between the wire 1WR and the wire 2WR enables driving the blue-violet semiconductor laser device 1, while application of voltage between the wire 1WR and the wire 3WR enables driving the red semiconductor laser device 2. In this manner, each of the blue-violet semiconductor laser device 1 and the red semiconductor laser device 2 can be driven independently.

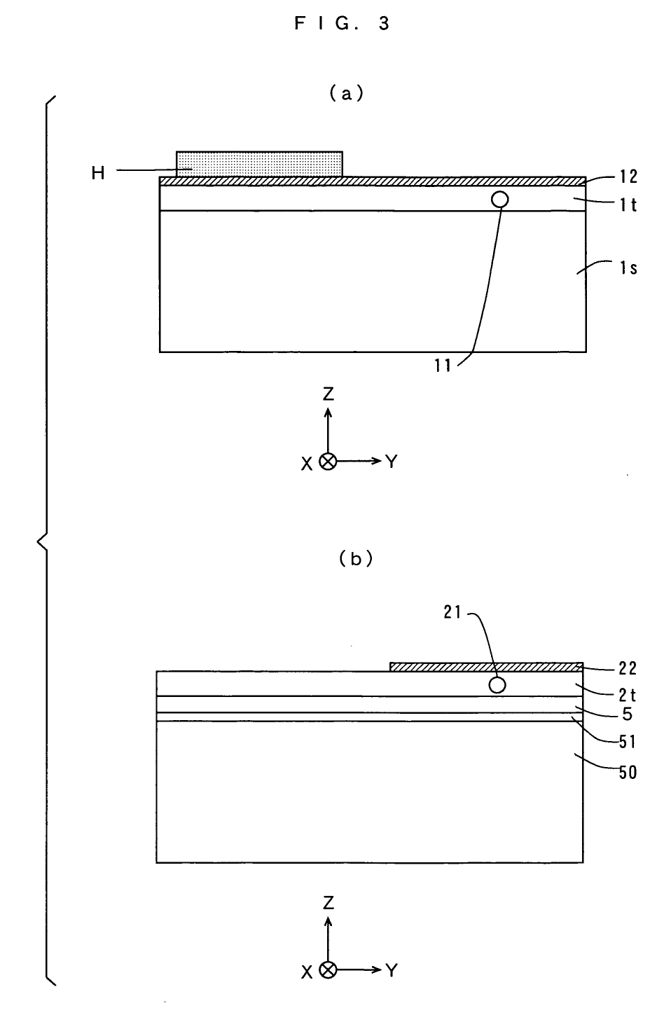

A fabrication method of the semiconductor laser apparatus 1000A according to the present embodiment will now be described. FIG. 3 to FIG. 6 are schematic cross sections showing exemplified steps of the fabrication method of the semiconductor laser apparatus according to the first embodiment. In FIG. 3 to FIG. 6 also, the X-, Y-, Z-directions are defined similarly as in FIG. 1.

In order to fabricate the blue-violet semiconductor laser device 1, a semiconductor layer it with a layered structure on one surface of an n-GaN substrate is formed, as shown in FIG. 3(a). Then, in order to bond the red semiconductor laser device 2 to the blue-violet semiconductor laser device 1, a p-electrode 12 is formed, and then a solder film H made of Au—Sn is formed on a predetermined region above the semiconductor layer lt.

A ridge portion (not shown) with a convex cross section that extends in the X-direction is formed on a predetermined portion on the semiconductor layer 1t in the Y-direction. Below the ridge portion of the semiconductor layer it, a blue-violet-beam-emission point 11 of the blue-violet semiconductor laser device 1 is formed. The predetermined region on which the solder film H is formed is arranged on the p-electrode 12 except above the blue-violet-beam-emission point 11. The n-electrode 15 of the blue-violet semiconductor laser device 1 will be formed in a subsequent step.

In order to fabricate the red semiconductor laser device 2, an etching stop layer 51 which is made of AlGaAs is formed on one surface of the n-GaAs substrate 50, followed by the formation of an n-GaAs contact layer 5 on the etching stop layer 51, as shown in FIG. 3(b).

Then, a semiconductor layer 2t with an AlGaInP layered structure is formed on the n-GaAs contact layer 5. Further, a p-electrode 22 is partially formed on the semiconductor layer 2t. The n-electrode 23 of the red semiconductor laser device 2 will be formed in a subsequent step.

A ridge portion (not shown) with a convex cross section that extends in the X-direction is formed on a predetermined portion on the semiconductor layer 2t in the Y-direction. Below the ridge portion of the semiconductor layer 2t, a red-beam-emission point 21 of the red semiconductor laser device 2 is formed. The p-electrode 22 is formed at least above the ridge portion.

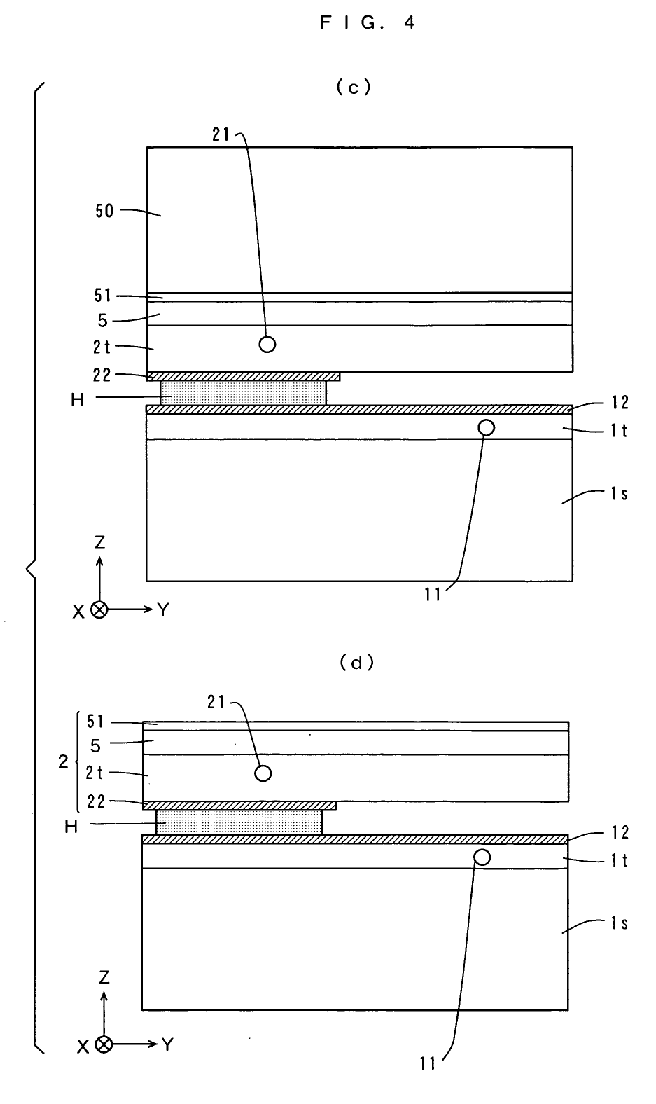

Next, the p-electrode 22 formed on the semiconductor layer 2t is bonded via the solder film H to a predetermined region of the p-electrode 12 (on which the solder film H is formed) on the semiconductor layer lt, as shown in FIG. 4(c).

At this time, the n-GaN substrate 1s and the n-GaAs substrate 50 both have a thickness of approximately 300 to 500 μm. This allows for easy handling of the n-GaN substrate 1s and n-GaAs substrate 50, thereby facilitate the bonding of the p-electrode 12 to the p-electrode 22.

The n-GaN substrate 1s of the blue-violet semiconductor laser device 1 is transparent. The n-GaN substrate 1s has such tranmittance and thickness that enables the red semiconductor laser device 2 to be visually seen through the n-GaN substrate 1s. Thus, the connection position of the p-electrode 12 with the p-electrode 22 can be visually seen through the n-GaN substrate 1s. This allows for easy positioning of the red semiconductor laser device 2 on the blue-violet semiconductor laser device 1. Consequently, accurate positioning of the light-beam-emission points can be achieved.

Note that in the present embodiment, the substrate of the blue-violet semiconductor laser device 1 is not restricted to the n-GaN substrate is, and it may also include other substrates which are conductive and optically transparent. This results in easy positioning of the red semiconductor laser device 2 on the blue-violet semiconductor laser device 1 as discussed previously, thus achieving accurate positioning of the light-beam-emission points.

The n-GaAs substrate 50 is thinned to a given thickness by etching, grinding or other processes, and subsequently etched to the etching stop layer 51, as shown in FIG. 4(d).

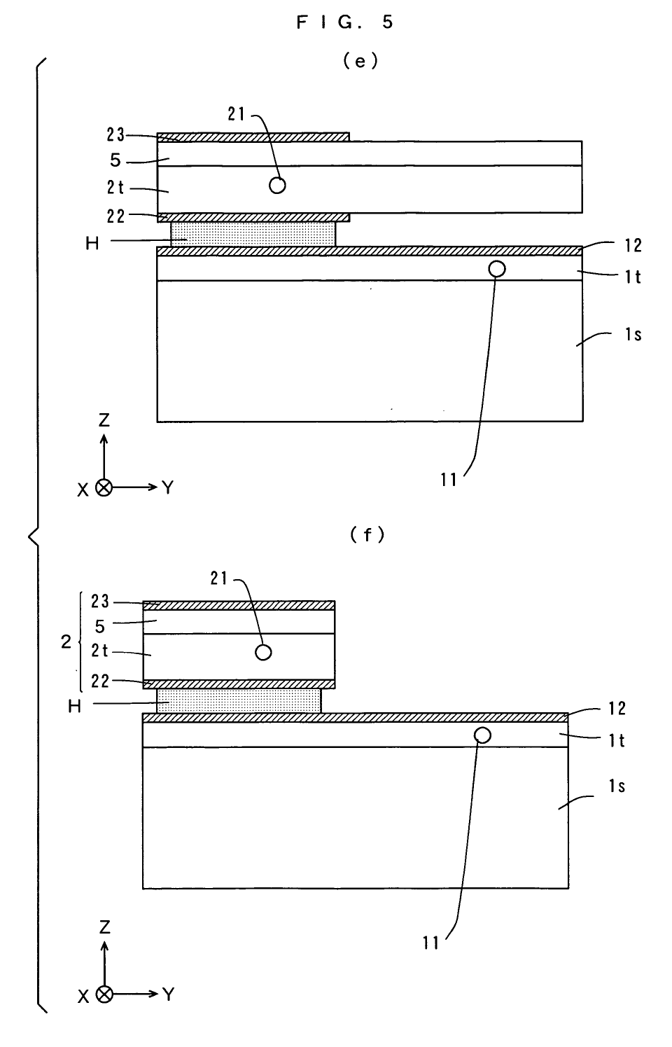

Following this, after the etching stop layer 51 has been etched away, an n-electrode 23 is formed by patterning on a region of the n-GaAs contact layer 5 above the semiconductor layer 2t, as shown in FIG. 5(e).

Then, the portions of the n-GaAs contact layer 5 and the semiconductor layer 2t which are positioned above the blue-violet-beam-emission point 11 of the semiconductor layer it are etched away, as shown in FIG. 5(f). This etching is performed until the p-electrode 12 on the semiconductor layer it becomes exposed. This results in the fabrication of the red semiconductor laser device 2. The structure of the red semiconductor laser device 2 will be discussed in detail below.

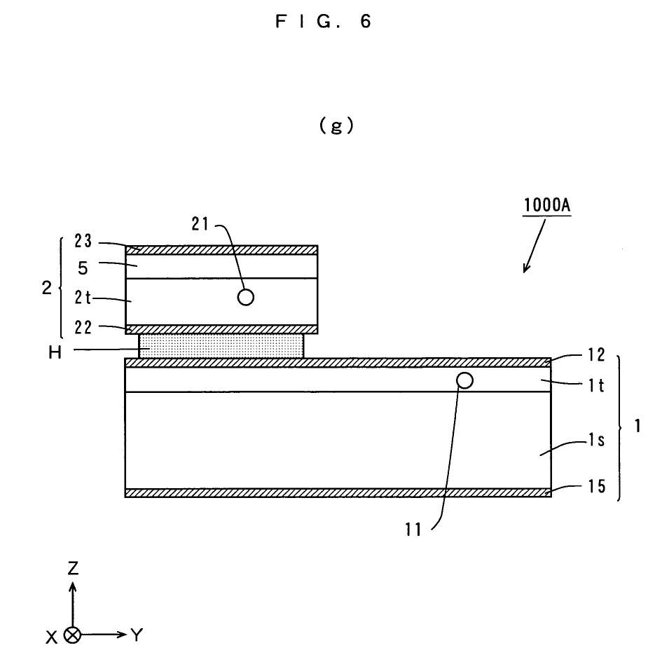

Then, after the n-GaN substrate is has been thinned by grinding, an n-electrode 15 is formed on the lower surface of the n-GaN substrate is, as shown in FIG. 6(g). This results in the fabrication of the blue-violet semiconductor laser device 1. The structure of the blue-violet semiconductor laser device 1 will be discussed in detail below.

Note that in the foregoing description of FIG. 3 to FIG. 6, the n-GaN substrate is and the semiconductor layer it of the blue-violet semiconductor laser device 1 extend in the Y-direction with a plurality of blue-violet-beam-emission points 11 formed at given spacings. The n-GaAs contact layer 5 and the semiconductor layer 2t of the red semiconductor laser device 2 also extend in the Y-direction with a plurality of red-beam-emission points 21 formed at given spacings.

Finally, the blue-violet semiconductor laser device 1 and red semiconductor laser device 2 thus fabricated are separated into bars by cleavage in the Y-direction to form cavity facets. After the formation of protection films over the cavity facets, the resulting bars are cut smaller and smaller into chips in the X-direction. Thus, the semiconductor laser apparatus 1000A according to the present embodiment is completed.

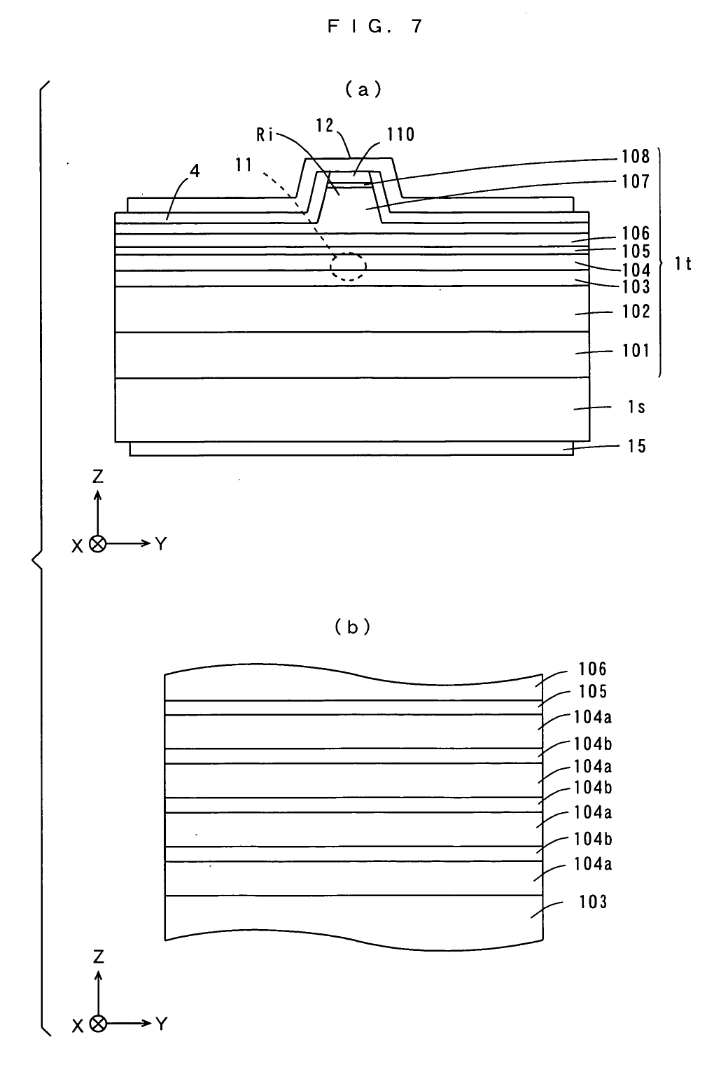

Now refer to FIGS. 7(a) and 7(b), the structure of the blue-violet semiconductor laser device 1 will be described in detail along with a fabrication method thereof.

FIGS. 7(a) and 7(b) are schematic cross sections for use in illustrating the structure of the blue-violet semiconductor laser device 1 in detail. In the description below also, the X-, Y-, Z-directions are defined similarly as in FIG. 1.

In the fabrication of the blue-violet semiconductor laser device 1, the semiconductor layer it with a layered structure is formed on the n-GaN substrate is, as described previously.

As shown in FIG. 7(a), the semiconductor layer it is formed on the n-GaN substrate is with a layered structure that includes in sequence, an n-GaN layer 101, an n-AlGaN cladding layer 102, an n-GaN optical guide layer 103, an MQW (multi-quantum well) active layer 104, an undoped AlGaN cap layer 105, an undoped GaN optical guide layer 106, a p-AlGaN cladding layer 107, and an undoped GaInN contact layer 108. Each of these layers is formed by MOCVD (metal organic chemical vapor deposition), for example.

The MQW active layer 104 has a structure which is composed of an alternate lamination of four undoped GaInN barrier layers 104a and three undoped GaInN well layers 104ba, as shown in FIG. 7(b).

The n-AlGaN cladding layer 102 has an Al composition of 0.15 and a Ga composition of 0.85, for example. The n-GaN layer 101, n-AlGaN cladding layer 102, and n-GaN optical guide layer 103 are each doped with Si.

The undoped GaInN barrier layer 104a has a Ga composition of 0.95 and an In composition of 0.05. The undoped GaInN well layer 104b has a Ga composition of 0.90 and an In composition of 0.10. The p-AlGaN cap layer 105 has an Al composition of 0.30 and a Ga composition of 0.70.

The p-AlGaN cladding layer 107 has an Al composition of 0.15 and a Ga composition of 0.85. The p-AlGaN cladding layer 107 is doped with Mg. The undoped GaInN contact layer 108 has a Ga composition of 0.95 and an In composition of 0.05.

A stripe-like ridge portion Ri that extends in the X-direction is formed in the p-AlGaN cladding layer 107 of the above-described semiconductor layer it. The ridge portion Ri in the p-AlGaN cladding layer 107 has a width of approximately 1.5 μm.

The undoped GaInN contact layer 108 is formed on the upper surface of the ridge portion Ri in the p-AlGaN cladding layer 107.

An insulating film 4 made of SiO₂ is formed on the upper surfaces of the p-AlGaN cladding layer 107 and undoped GaInN contact layer 108, followed by etching away a portion of the insulating film 4 formed on the undoped GaInN contact layer 108. Then, a p-electrode 110 made of Pd/Pt/Au is formed on the undoped GaInN contact layer 108 exposed outside. Following this, a p-electrode 12 is formed to cover the upper surfaces of the p-electrode 110 and insulating film 4 by sputtering, vacuum evaporation, or electron beam evaporation.

In this manner, the semiconductor layer lt with the layered structure on the one surface of the n-GaN substrate 1s is formed. On the other surface of the n-GaN substrate is, an n-electrode 15 made of Ti/Pt/Au is formed.

The blue-violet semiconductor laser device 1 has a blue-violet-beam-emission point 11 which is formed at a position in the MQW active layer 104 below the ridge portion Ri. In the present embodiment, the MQW active layer 104 corresponds to the p-n junction surface 10 of FIG. 1.

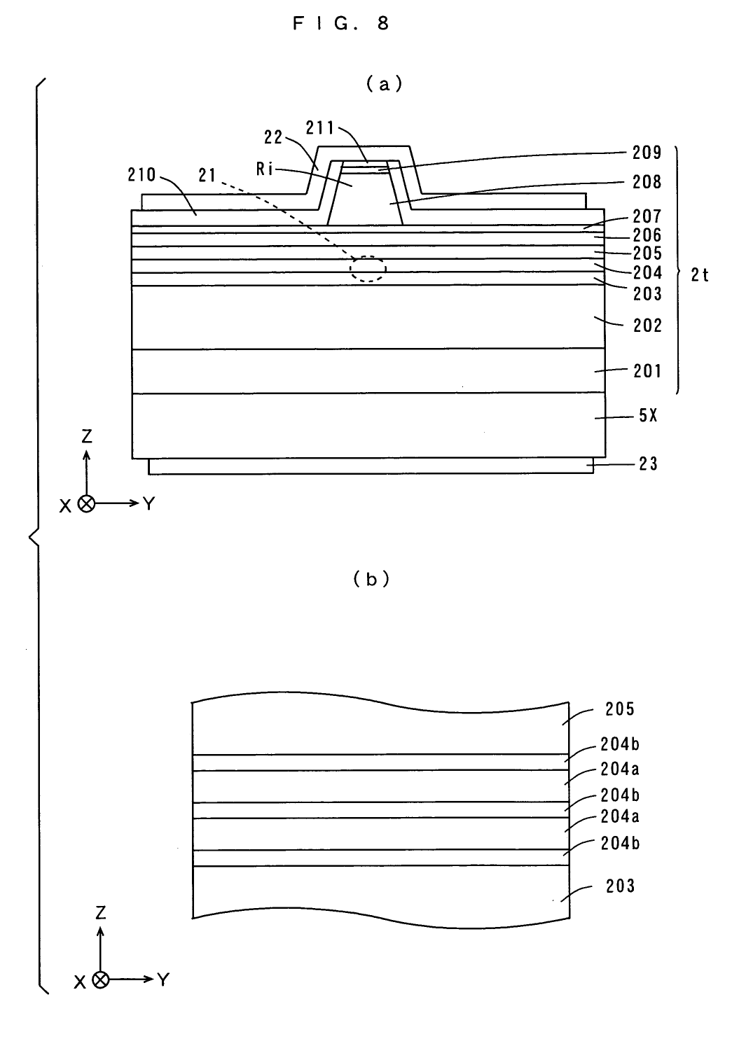

Now refer to FIGS. 8(a) and 8(b), the structure of the red semiconductor laser device 2 will be described in detail along with a fabrication method thereof.

FIGS. 8(a) and 8(b) are schematic cross sections for use in illustrating the structure of the red semiconductor laser device 2 in detail. In the description below also, the X-, Y-, Z-directions are defined similarly as in FIG. 1. Although in the present embodiment, the red semiconductor laser device 2 is fabricated by forming the semiconductor layer 2t on the n-GaAs contact layer 5, in the description below, a semiconductor layer 2t is formed on an n-GaAs substrate 5X instead of the n-GaAs contact layer 5. The n-GaAs substrate 5X is doped with Si.

As shown in FIG. 8(a), the semiconductor layer 2t is formed on the n-GaAs substrate 5X which has a layered structure that includes in sequence, an n-GaAs layer 201, an n-AlGaInP cladding layer 202, an undoped AlGaInP optical guide layer 203, an MQW (multi-quantum well) active layer 204, an undoped AlGaInP optical guide layer 205, a p-AlGaInP first cladding layer 206, a p-InGaP etching stop layer 207, a p-AlGaInP second cladding layer 208, and a p-contact layer 209. Each of these layers is formed by MOCVD (metal organic chemical vapor deposition) for example.

The MQW active layer 204 has a structure which is composed of an alternate lamination of two undoped AlGaInP barrier layers 204a and three undoped InGaP well layers 204b, as shown in FIG. 8(b).

The n-AlGaInP cladding layer 202 has an Al composition of 0.70, a Ga composition of 0.30, an In composition of 0.50, and a P composition of 0.50, for example. The n-GaAs layer 201 and n-AlGaInP cladding layer 202 are each doped with Si.

The undoped AlGaInP optical guide layer 203 has an Al composition of 0.50, a Ga composition of 0.50, an In composition of 0.50, and a P composition of 0.50.

The undoped AlGaInP barrier layer 204a has an Al composition of 0.50, a Ga composition of 0.50, an In composition of 0.50, and a P composition of 0.50. The undoped InGaP well layer 204b has an In composition of 0.50 and a Ga composition of 0.50. The undoped AlGaInP optical guide layer 205 has an Al composition of 0.50, a Ga composition of 0.50, an In composition of 0.50, and a P composition of 0.50.

The p-AlGaInP first cladding layer 206 has an Al composition of 0.70, a Ga composition of 0.30, an In composition of 0.50, and a P composition of 0.50. The p-InGaP etching stop layer 207 has an In composition of 0.50 and a Ga composition of 0.50.

The p-AlGaInP second cladding layer 208 has an Al composition of 0.70, a Ga composition of 0.30, an In composition of 0.50, and a P composition of 0.50.

The p-contact layer 209 has a layered structure of a p-GaInP layer and a p-GaAs layer. The p-GaInP has a Ga composition of 0.5 and an In composition of 0.5.

Note that the composition of the above-mentioned AlGaInP materials can be expressed in a general formula; (AlₐGa_{b})_{0.5}In_{c}P_{d}, wherein a is the Al composition, b is the Ga composition, c is the In composition, and d is the P composition.

The p-GaInP and p-GaAs in each of the p-AlGaInP first cladding layer 206, p-InGaP etching stop layer 207, p-AlGaInP second cladding layer 208, and p-contact layer 209 are doped with Zn.

The p-AlGaInP second cladding layer 208 is formed only on a portion (central portion) of the p-InGaP etching stop layer 207 in the above-described example. Then, the p-contact layer 209 is formed on the upper surface of the p-AlGaInP second cladding layer 208.

In this manner, the p-AlGaInP second cladding layer 208 and p-contact layer 209 of the above-described semiconductor layer 2t form a strip-like ridge portion Ri that extends in the X-direction. The ridge portion Ri formed by the p-AlGaInP second cladding layer 208 and the p-contact layer 209 has a width of approximately 2.5 μm.

An insulating film 210 made of SiO₂ is formed on the upper surface of the p-InGaP etching stop layer 207, on the sides of the p-AlGaInP second cladding layer 208, and on the upper surface and sides of the p-contact layer 209, and then a portion of the insulating film formed on the upper surface of the p-contact layer 209 is etched away. A p-electrode 211 made of Cr/Au is subsequently formed on the p-contact layer 209 exposed outside. Following this, a p-electrode 22 is formed to cover the upper surfaces of the p-electrode 211 and insulating film 210 by sputtering, vacuum evaporation, or electron beam evaporation.

In this manner, the semiconductor layer 2t with the layered structure on the one surface of the n-GaAs substrate 5X is formed. On the other surface of the n-GaAs substrate 5X, an n-electrode 23 made of AuGe/Ni/Au is formed.

The red semiconductor laser device 2 has the red-beam-emission point 21 which is formed at a position in the MQW active layer 204 below the ridge portion Ri. In the present embodiment, the MQW active layer 204 corresponds to the p-n junction surface 20 of FIG. 1.

In the foregoing semiconductor laser 1000A according to the present embodiment, the red semiconductor laser device 2 is laminated on the blue-violet semiconductor laser device 1 such that the red semiconductor laser deice 2 does not overlap with the blue-violet-beam-emission point 11 of the blue-violet semiconductor laser device 1 in the Z-direction vertical to the one surface of the n-GaN substrate 1s.

Thus, when the semiconductor laser apparatus 1000A is mounted on the heat sink 500 as shown in FIG. 2, the heat produced from the blue-violet-beam-emission point 11 of the blue-violet semiconductor laser device 1 is efficiently dissipated into the heat sink 500 without being inhibited by the red semiconductor laser device 2. Also, the heat produced from the red semiconductor laser device 2 is efficiently dissipated into the heat sink 500 without being inhibited by the blue-violet semiconductor laser device 1. This results in enhanced temperature characteristics and reliability.

Also, in the present embodiment, the red semiconductor laser device 2 is laminated on the blue-violet semiconductor laser device 1 such that the semiconductor layer 2t side is positioned on the semiconductor layer lt side. Since the red semiconductor laser device 2 is thus laminated on the blue-violet semiconductor laser device 2 such that the semiconductor layer 2t side is positioned on the semiconductor layer lt side, the distance between the light-beam-emission points of the blue-violet semiconductor laser device 1 and red semiconductor laser device 2 becomes shorter. This allows the light-beam-emission points of both the blue-violet semiconductor laser device 1 and red semiconductor laser device 2 to become closer to the center of the semiconductor laser apparatus 1000A. This results in enhanced light extraction efficiencies of both the blue-violet semiconductor laser device 1 and red semiconductor laser device 2 when converging laser beams through a lens, for example.

In addition, the semiconductor layer lt described above is made of a nitride-based semiconductor. Since the semiconductor lt is thus made of the nitride-based semiconductor with high thermal conductivity, the heat dissipation from the semiconductor layer lt of the blue-violet semiconductor laser device 1 is enhanced. This results in enhanced temperature characteristics and reliability of the blue-violet semiconductor laser device 1. This also enables emission of a blue-violet laser beam with short wavelength.

In this embodiment, the semiconductor laser apparatus 1000A is fabricated by integrating the blue-violet semiconductor laser device 1 and the red semiconductor laser device 2; however, the number of semiconductor laser devices may be any number. The plurality of semiconductor laser devices may alternatively be semiconductor laser devices which emit light with different wavelengths.

In this embodiment, the semiconductor laser apparatus 1000A is mounted on the heat sink 500 as shown in FIG. 2. The material of the heat sink 500 may include insulative materials such as AlN, SiC, Si or diamond, or conductive materials such as Cu, CuW or Al. In this embodiment, the heat sink 500 is preferably made of an insulative material. If the heat sink 500 is made of a conductive material, it is necessary to coat the surfaces thereof with an insulative film.

A package for the semiconductor laser apparatus 1000A may be of any type that can house the semiconductor laser apparatus 1000A, which includes a can package made of metal or a frame package made of resins, for example.

### Second Embodiment

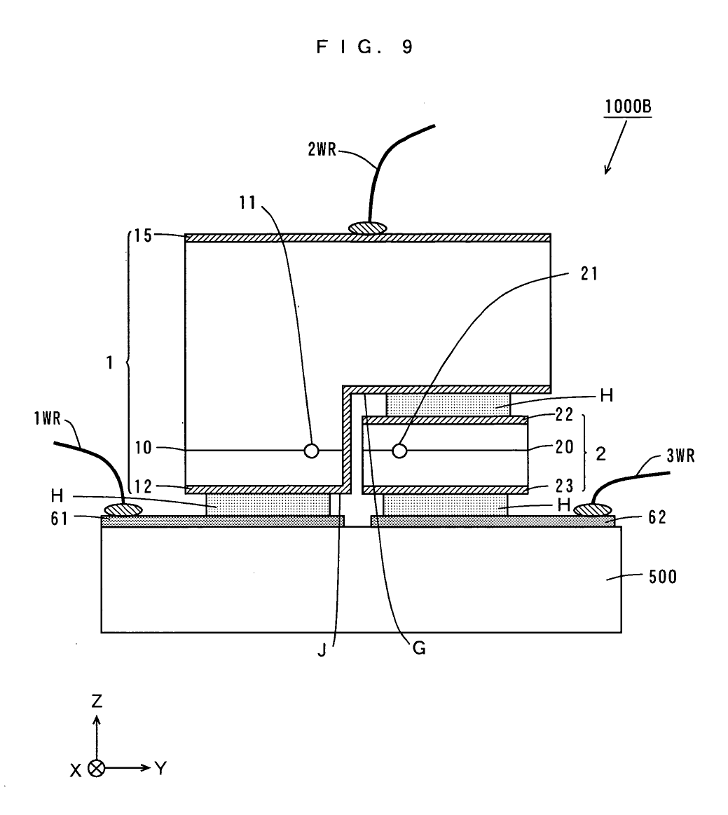

FIG. 9 is a schematic cross section of a semiconductor laser apparatus according to a second embodiment when assembled on a heat sink. In the description below also, the X-, Y-, and Z-directions are defined similarly as in FIG. 1.

The semiconductor laser apparatus 1000B according to the second embodiment differs in structure from the semiconductor laser apparatus 1000A according to the first embodiment as follows.

As shown in FIG. 9, one surface of the blue-violet semiconductor laser device 1 in the present embodiment has a difference in level formed by an upper level surface J and a lower level surface G. The blue-violet semiconductor laser device 1 also has a p-electrode 12 which is formed to extend continuously from the upper level surface J to the lower level surface G on the one surface thereof and an n-electrode 15 which is formed on the other surface thereof.

The blue-violet semiconductor laser device 1 has a p-n junction surface 10 which is formed to extend in the Y-direction along a predetermined portion between the upper level surface J and the lower level surface G in the Z-direction and a blue-violet-beam-emission point 11 which is formed at a predetermined region of the p-n junction surface 10.

A solder film H is partially formed on the lower level surface G, and the lower level surface G of the blue-violet semiconductor laser device 1 is bonded via the solder film H to the p-electrode 22 of the red semiconductor laser device 2.

The red semiconductor laser device 2 has a p-n junction surface 20 which is formed at substantially the same level as the p-n junction surface 10 of the blue-violet semiconductor laser device 1. In this manner, the blue-violet-beam-emission point 11 and the red-beam-emission point 21 are formed in alignment in the Y-direction.

Moreover, the red semiconductor laser device 2 is bonded to the lower level surface G of the blue-violet semiconductor laser device 1, so that the oppositely facing surface (n-electrode 23) is formed at substantially the same level as the upper level surface J of the blue-violet semiconductor laser device 1 in the X- and Y-directions.

Meanwhile, the heat sink 500, onto which the semiconductor laser apparatus 1000B is assembled, has an upper surface which is flat in the X- and Y-directions, where two patterning electrodes 61, 62 are partially formed separately from each other. Note that at least the surfaces of the heat sink 500 are made of an insulative material as described above, so that the patterning electrodes 61, 62 are electrically isolated from each other.

A solder film H is partially formed on the patterning electrode 61, and a solder film H is partially formed on the patterning electrode 62.

This allows the upper level surface J of the p-electrode 12 in the blue-violet semiconductor laser device 1 to be bonded to the patterning electrode 61 via the solder film H. Meanwhile, the n-electrode 23 of the red semiconductor laser device 2, which is bonded to the blue-violet semiconductor laser device 1, is bonded to the patterning electrode 62 via the solder film H.

The p-electrode 12 of the blue-violet semiconductor laser device 1 is continuously formed from the upper level surface J to the lower level surface G, as described above.

This results in an electrical connection among the p-electrode 12 of the blue-violet semiconductor laser device 1, the p-electrode 22 of the red semiconductor laser device 2, and the patterning electrode 61. The n-electrode 23 of the red semiconductor laser device 2 and the patterning electrode 62 are also electrically connected.

In this state, the p-electrode 12 and n-electrode 15 of the blue-violet semiconductor laser device 1 as well as the p-electrode 22 and n-electrode 23 of the red semiconductor laser device 2 are wired, using wires 1WR, 2WR, 3WR.

The patterning electrode 61, which is bonded to the p-electrode 12 of the blue-violet semiconductor laser device 1 and the p-electrode 22 of the red semiconductor laser device 2, is connected to a driving circuit (not shown) through the wire 1WR. The n-electrode 15 of the blue-violet semiconductor laser device 1 is connected to the driving circuit (not shown) through the wire 2WR. The patterning electrode 62, which is bonded to the n-electrode 23 of the red semiconductor laser device 2, is connected to the driving circuit (not shown) through the wire 3WR.

Application of voltage between the wire 1WR and the wire 2WR enables driving the blue-violet semiconductor laser device 1, while application of voltage between the wire 1WR and the wire 3WR enables driving the red semiconductor laser device 2. In this manner, each of the blue-violet semiconductor laser device 1 and red semiconductor laser device 2 can be driven independently.

In the foregoing semiconductor laser 1000B according to the present embodiment, the blue-violet semiconductor laser device 1 has the difference in level that is formed by the upper level surface J and the lower level surface G. Also, the blue-violet-beam-emission point 11 in the semiconductor layer lt is situated at the predetermined position in the Z-direction of the upper level surface J, and the red semiconductor laser device 2 is laminated on the lower level surface G of the blue-violet semiconductor laser device 1.

In this manner, the red semiconductor laser device 2 is laminated on the lower level surface G of the blue-violet semiconductor laser device 1, so that the upper level surface J of the blue-violet semiconductor laser device 1 and the surface of the laminated red semiconductor laser device 2 on the n-electrode 23 side can be formed at substantially the same level. This allows the upper level surface J of the blue-violet semiconductor laser device 1 and the surface of the red semiconductor laser device 2 on the n-electrode 23 side to bring into contact with the flat surface of the heat sink 500. As a result, the use of a flat, inexpensive heat sink is possible, which allows for reduced manufacturing cost of the semiconductor laser apparatus 1000B and optical pickup apparatus.

Moreover, the blue-violet-beam-emission point 11 of the semiconductor layer it in the blue-violet semiconductor laser device 1 is situated between the upper level surface J and the lower level surface G in the Z-direction, and the red-beam-emission point 21 of the semiconductor layer 2t in the red semiconductor laser device 2 is situated between the upper level surface J and the lower level surface G of the blue-violet semiconductor laser device 1 in the Z-direction. This allows the blue-violet-beam-emission point 11 of the blue-violet semiconductor laser device 1 and the red-beam-emission point 21 of the red semiconductor laser device 2 to align in parallel with the one surface of the n-GaN substrate is. This facilitates the designs of the semiconductor laser apparatus 1000B and the optical pickup apparatus.

In this embodiment, the red semiconductor laser device 2 is directly bonded to the heat sink 500, resulting in enhanced heat dissipation. The blue-violet semiconductor laser device 1 also is directly bonded to the heat sink 500 with the blue-violet-beam-emission point 11 located near the connection position of the heat sink 500 and the p-electrode 12, resulting in enhanced heat dissipation.

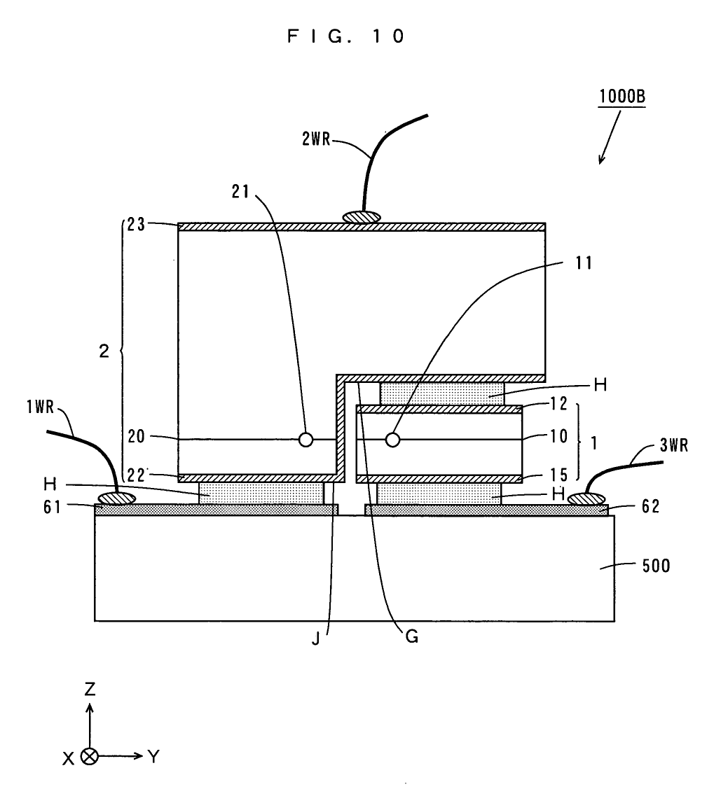

In this embodiment, the blue-violet semiconductor laser device 1 has the difference in level as described above, and the red semiconductor laser device 2 is bonded to the lower level surface G of the blue-violet semiconductor laser device 1. However, other structures are also possible, for example the structure shown in FIG. 10 where the blue-violet semiconductor laser device 1 is bonded to the lower level surface G of the red semiconductor laser device 2 with a difference in level.

FIG. 10 is a schematic cross section of a semiconductor laser apparatus according to another example of the second embodiment when assembled on a heat sink.

In this case also, the blue-violet semiconductor laser device 1 and the red semiconductor laser device 2 provide enhanced heat dissipation. Note that the positions of the blue-violet-beam-emission point 11 and the red-beam-emission point 21 are reversed.

### Third Embodiment

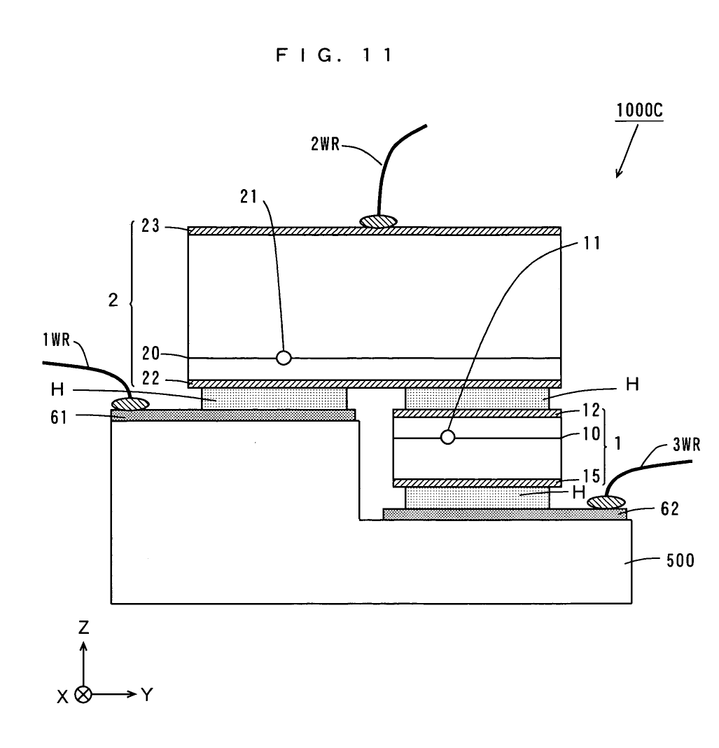

FIG. 11 is a schematic cross section of a semiconductor laser apparatus according to a third embodiment when assembled on a heat sink. In the description below also, the X-, Y-, and Z-directions are defined similarly as in FIG. 1.

The semiconductor laser apparatus 1000C according to the third embodiment differs in structure from the semiconductor laser apparatus 1000A according to the first embodiment as follows.

In the present embodiment, the p-electrode 12 of the blue-violet semiconductor laser device 1 is partially bonded to the p-electrode 22 of the red semiconductor laser device 2 via a solder film H, as shown in FIG. 11.

The patterning electrode 61 which is formed on the upper level surface of the heat sink 500 is bonded to the p-electrode 22 of the red semiconductor laser device 2 via a solder film H. The patterning electrode 62 which is formed on the lower level surface of the heat sink 500 is bonded to the n-electrode 15 of the blue-violet semiconductor laser device 1 via a solder film H.

The red-beam-emission point 21 in the semiconductor layer 2t of the red semiconductor laser device 2 is formed at a distance away in the Y-direction from the connection position of the red semiconductor laser device 2 and the blue-violet semiconductor laser device 1. This allows the heat produced from the red-beam-emission point 21 to be dissipated into the upper level surface of the heat sink 500 without being inhibited by the blue-violet semiconductor laser device 1, thus resulting in enhanced heat dissipation of the red semiconductor laser device 2.

Moreover, the heat produced from the blue-violet-beam-emission point 11 is dissipated to the lower level surface of the heat sink 500 without being inhibited by the red semiconductor laser device 2, resulting in enhanced heat dissipation of the blue-violet semiconductor laser device.

### Fourth Embodiment

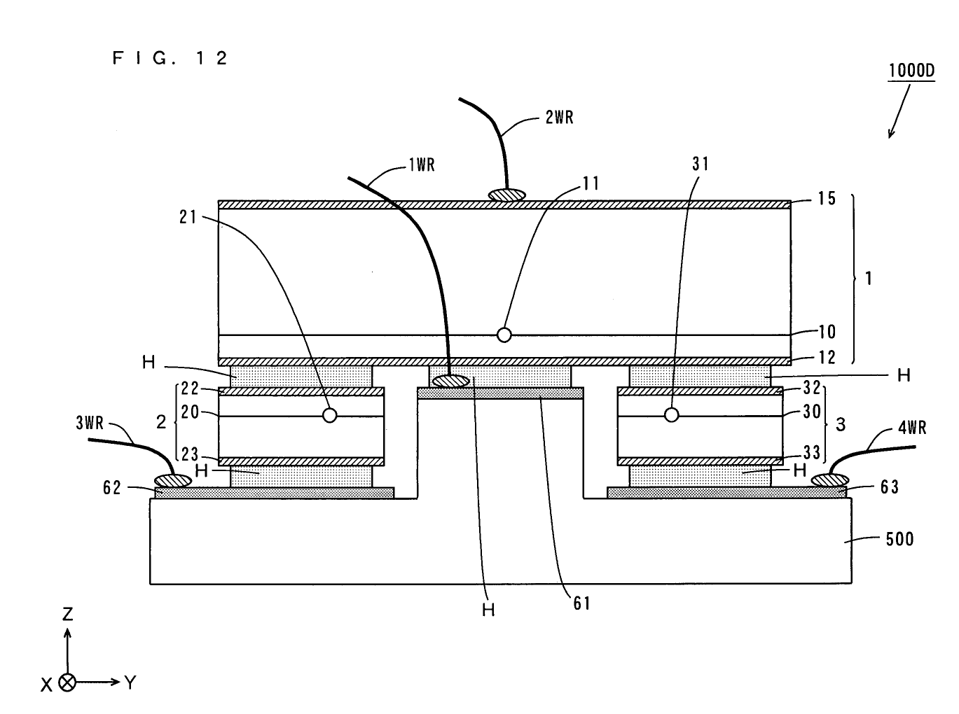

FIG. 12 is a schematic cross section of a semiconductor laser apparatus according to a fourth embodiment when assembled on a heat sink. In the description below also, the X-, Y-, and Z-directions are defined similarly as in FIG. 1.

The semiconductor laser apparatus 1000D according to the fourth embodiment differs in structure from the semiconductor laser apparatus 1000A according to the first embodiment as follows.

The semiconductor laser apparatus 1000D includes a semiconductor laser apparatus (hereinafter referred to as an infrared semiconductor laser device) 3 which emits a laser beam with a wavelength of approximately 780 nm along with a blue-violet semiconductor device 1 and a red semiconductor laser device 2.

The infrared semiconductor laser device 3 is fabricated by forming semiconductor layers on a GaAs substrate.

More specifically, the semiconductor layers are formed on an n-GaAs substrate that is doped with Si. The semiconductor layers with a layered structure are formed on the n-GaAs substrate, which include in sequence, an n-GaAs layer, an n-AlGaAs cladding layer, an undoped AlGaAs optical guide layer, an MQW (multi-quantum well) active layer, an undoped AlGaAs optical guide layer, a p-AlGaAs first cladding layer, a p-AlGaAs etching stop layer, a p-AlGaAs second cladding layer, and a p-GaAs contact layer. Each of these layers is formed by MOCVD (metal organic chemical vapor deposition), for example.

The MQW active layer has a structure which is composed of an alternate lamination of two undoped AlGaAs barrier layers and three undoped AlGaAs well layers, for example.

The infrared semiconductor laser device 3 has a p-electrode 32 formed on one surface thereof and an n-electrode 33 formed on the other surface thereof, as shown in FIG. 12. The infrared semiconductor laser device 3 has a p-n junction surface 30 where a p-type semiconductor and an n-type semiconductor are joined. An infrared-beam-emission point 31 is formed at a predetermined position of the p-n junction surface 30.

In this embodiment, the p-electrode 22 of the red semiconductor laser device 2 and the p-electrode 32 of the infrared semiconductor laser device 3 are partially bonded to the p-electrode 12 of the blue-violet semiconductor laser device 1 via solder films H, respectively.

Note that the connection positions of the red semiconductor laser device 2 and the infrared semiconductor laser device 3 with the blue-violet semiconductor laser device 1 are each provided at a distance away in the Y-direction from the blue-violet-beam-emission point 11 of the blue-violet semiconductor laser device 1.

The heat sink 500 is formed with a convex cross section in the X-direction. A patterning electrode 61 is formed on the upper surface of the convex portion of the heat sink 500, to which the p-electrode 12 of the blue-violet semiconductor laser device 1 is bonded via a solder film H.

A patterning electrode 62 is formed on the lower surface on one side (in the Y-direction) of the convex portion of the heat sink 500. The patterning electrode 62 is bonded with the n-electrode 23 of the red semiconductor laser device 2 via the solder film H.

A patterning electrode 63 is formed on the lower surface on the other side (in the Y-direction) of the convex portion of the heat sink 500. The patterning electrode 63 is bonded with the n-electrode 33 of the infrared semiconductor laser device 3 via the solder film H.

A predetermined portion of the patterning electrode 61 is exposed in the x-direction. The exposed patterning electrode 61 is connected to a driving circuit (not shown) through a wire 1WR. The patterning electrode 61 is electrically connected with the p-electrode 12 of the blue-violet semiconductor laser device 1, the p-electrode 22 of the red semiconductor laser device 2, and the p-electrode 32 of the infrared semiconductor laser device 3.

As with the first embodiment, the n-electrode 15 of the blue-violet semiconductor laser device 1 is connected to the driving circuit (not shown) through a wire 2WR. The patterning electrode 62, which is bonded with the n-electrode 23 of the red semiconductor laser device 2, is connected to the driving circuit (not shown) through a wire 3WR. The patterning electrode 63, which is bonded with the n-electrode 33 of the infrared semiconductor laser device 3, is connected to the driving circuit (not shown) through a wire 4WR.

Application of voltage between the wire 1WR and the wire 2WR enables driving the blue-violet semiconductor laser device 1, while application of voltage between the wire 1WR and the wire 3WR enables driving the red semiconductor laser device 2. Similarly, application of voltage between the wire 1WR and the wire 4WR enables driving the infrared semiconductor laser device 3. In this manner, each of the blue-violet semiconductor laser device 1, red semiconductor laser device 2, and infrared semiconductor laser device 3 can be driven independently.

In the semiconductor laser apparatus 1000D according to the present embodiment, the red semiconductor laser device 2 and the infrared semiconductor laser device 3 are bonded to the blue-violet semiconductor laser device 1 except the region that overlaps with the blue-violet-beam-emission point 11 of the blue-violet semiconductor laser device 1 in the Y-direction.

This allows the heat produced from the blue-violet-beam-emission point 11 of the blue-violet semiconductor laser device 1 to be efficiently dissipated without being inhibited by the red semiconductor laser device 2 and the infrared semiconductor laser device 3.

Also, the heat produced from the red semiconductor laser device 2 and the infrared semiconductor laser device 3 is efficiently dissipated without being inhibited by the blue-violet-beam-emission point 11 of the blue-violet semiconductor laser device 1. This results in enhanced temperature characteristics and reliability.

In the foregoing first embodiment to fourth embodiment, the n-GaN substrate is corresponds to a first substrate, the laser beam with a wavelength of approximately 400 nm corresponds to a light beam with a first wavelength, the semiconductor layer it corresponds to a first semiconductor layer, and the blue-violet semiconductor laser device 1 corresponds to a first semiconductor laser device.

The n-GaAs contact layer 5 and n-GaAs substrates 50 and 5X correspond to a second substrate, the laser beam with a wavelength of approximately 650 nm corresponds to a light beam with a second wavelength, the semiconductor layer 2t corresponds to a second semiconductor layer, and the red semiconductor laser device 2 corresponds to a second semiconductor laser device.

The GaAs substrate of the infrared semiconductor laser device 3 corresponds to a third substrate, the laser beam with a wavelength of approximately 780 nm corresponds to a light beam with a third wavelength, and the infrared semiconductor laser device 3 corresponds to a third semiconductor laser device.

The blue-violet-beam-emission point 11, red-beam-emission point 21, and infrared-beam-emission point 31 correspond to light-beam-emission points, the upper level surface J corresponds to an upper level surface, the lower level surface G corresponds to a lower level surface, and the heat sink 500 corresponds to a heat dissipator.

The n-GaN substrate is corresponds to an optically transparent substrate, the upper level surface of the heat sink 500 of FIG. 2 and the lower level surface of the heat sink 500 of FIG. 11 each correspond to a first surface, the lower level surface of the heat sink 500 of FIG. 2 and the upper level surface of the heat sink 500 of FIG. 11 each correspond to a second surface, and the semiconductor layers formed on the GaAs substrate of the infrared semiconductor laser device 3 correspond to a third semiconductor layer.

Although the present invention has been described and illustrated in detail, it is clearly understood that the same is by way of illustration and example only and is not to be taken by way of limitation, the spirit and scope of the present invention being limited only by the terms of the appended claims.

1. A semiconductor laser apparatus comprising:
a first semiconductor laser device having on a first substrate a first semiconductor layer that emits a light beam with a first wavelength; and
a second semiconductor laser device having on a second substrate a second semiconductor layer that emits a light beam with a second wavelength, wherein
said first and said second wavelengths are different from each other, and materials of said first and said second substrates are different from each other, and
said second semiconductor laser device is laminated on said first semiconductor laser device so as not to overlap with a light-beam-emission point of said first semiconductor laser device in a vertical direction to one surface of said first substrate.

2. The semiconductor laser apparatus according to claim 1, wherein
said first semiconductor laser device has a difference in level formed by an upper level surface and a lower level surface, the light-beam-emission point of said first semiconductor layer being arranged below said upper level surface, and
said second semiconductor laser device is laminated on the lower level surface of said first semiconductor laser device.

3. The semiconductor laser apparatus according to claim 1, wherein
said second semiconductor laser device is laminated on said first semiconductor laser device such that said second semiconductor layer side is positioned on said first semiconductor layer side.

4. The semiconductor laser apparatus according to claim 1, wherein
either of said first semiconductor layer and said second semiconductor layer is made of a nitride-based semiconductor.

5. The semiconductor laser apparatus according to claim 1, wherein
said first substrate is an optically transparent substrate.

6. The semiconductor laser apparatus according to claim 1, wherein
said second semiconductor laser device is laminated on said first semiconductor laser device such that said first semiconductor layer is positioned on said second semiconductor laser device side.

7. The semiconductor laser apparatus according to claim 1, wherein
either of said first semiconductor layer and said second semiconductor layer includes a gallium arsenide-based semiconductor or a gallium indium phosphide-based semiconductor.

8. The semiconductor laser apparatus according to claim 1, wherein
a heat dissipator is arranged in contact with a region on said first semiconductor laser device which overlaps with the light-beam-emission point of said first semiconductor layer and a surface of said second semiconductor laser device on the opposite side of said first semiconductor laser device.

9. The semiconductor laser apparatus according to claim 8, wherein
said second semiconductor laser device is laminated on said first semiconductor laser device, so that one surface of said first semiconductor laser device and one surface of said second semiconductor laser device form a difference in level, and
said heat dissipator is provided with a difference in level formed by a first surface in contact with the one surface of said first semiconductor laser device and a second surface in contact with the one surface of said second semiconductor laser device.

10. The semiconductor laser apparatus according to claim 1, further comprising a third semiconductor laser device having a third semiconductor layer on a third substrate that emits a light beam with a third wavelength, wherein
said third semiconductor laser device is laminated on said first semiconductor laser device except a region that overlaps with the light-beam-emission point of said first semiconductor laser device in a parallel direction with the one surface of said first substrate.

11. The semiconductor laser apparatus according to claim 10, wherein
said second and said third semiconductor laser devices are laminated on said first semiconductor laser device such that said first semiconductor layer is positioned on said second and said third semiconductor laser devices sides.

12. The semiconductor laser apparatus according to claim 10, wherein
said second semiconductor laser device is laminated on said first semiconductor laser device such that said second semiconductor layer side is positioned on said first semiconductor layer side.

13. The semiconductor laser apparatus according to claim 10, wherein
said third semiconductor laser device is laminated on said first semiconductor laser device such that said third semiconductor layer side is positioned on said first semiconductor layer side.

14. The semiconductor laser apparatus according to claim 10, wherein
said first, said second, and said third wavelengths are different from one another, and said first, said second, and said third semiconductor layers include any of a nitride-based semiconductor, a gallium arsenide-based semiconductor or a gallium indium phosphide-based semiconductor.

15. The semiconductor laser apparatus according to claim 10, wherein
a heat dissipator is arranged in contact with a region on said first semiconductor laser device which overlaps with the light-beam-emission point of said first semiconductor layer, a surface of said second semiconductor laser device on the opposite side of said first semiconductor laser device, and a surface of said third semiconductor laser device on the opposite side of said first semiconductor laser device.

16. A method of fabricating a semiconductor laser apparatus comprising the steps of:
forming on a first substrate a first semiconductor layer such that said first semiconductor layer has a plurality of first light-beam-emission points that emit light beams with a first wavelength;
forming a second semiconductor layer on a second substrate made of a different material from that of said first substrate such that said second semiconductor layer has a plurality of second light-beam-emission points that emit light beams with a second wavelength different from said first wavelength;
bonding said first substrate and said second substrate such that said second semiconductor layer is laminated on said first semiconductor layer;
etching said second substrate and said second semiconductor layer such that regions of said first semiconductor layer above said plurality of first light-beam-emission points become exposed; and
dividing a layered structure of said first semiconductor layer, said second substrate, and said second semiconductor layer into a plurality of semiconductor laser apparatuses.
